(19) United States
(12) Patent Application Publication
(10) Pub. No.: US 2021/0060677 A1
(43) Pub. Date: Mar. 4, 2021

(54) Soldering nozzle and method for the production thereof

(71) Applicant: SEHO Systemtechnik GmbH, Kreuzwertheim (DE)

(72) Inventors: Thomas Herz, Kreuzwertheim (DE); Andreas Reinhardt, Schönfeld (DE); Markus Walter, Wertheim (DE)

(21) Appl. No.: 16/942,878

(22) Filed: Jul. 30, 2020

(30) Foreign Application Priority Data
Aug. 30, 2019 (DE) 10-2019 123 294.5
Jul. 13, 2020 (DE) 10 2020 118 399.2

(51) Int. Cl. B23K 3/06

(52) U.S. Cl. CPC B23K 3/0638

(57) ABSTRACT

A soldering nozzle (100) for selectively soldering assemblies by means of molten solder supplied through a soldering nozzle (100) from a solder bath. The soldering nozzle (100) is designed as a deep-drawn part. A method for the production of a soldering nozzle (100) is specified as well, including the provision of a blank (401); the drawing of the blank (401) through at least one female die (411, 421) by means of at least one male die (413, 422, 431) to produce an oblong shape (439) of locally annular or substantially annular cross-section, with a first end (436) corresponding to an action point of the male die (413, 422, 431) and a second end (437) corresponding to an introduction cross-section of the male die (413, 422, 431), the cross-section preferably increasing from the first end (436) towards the second end (437); and the formation of an opening (446) at the tip end (436).

### RELATED APPLICATIONS

This application claims priority to German Patent Applications No. 10 2019 123 294.5, filed on 30 Aug. 2019, and No. 10 2020 118 399.2, filed on 13 Jul. 2020, both of which are incorporated herein by reference in their entirety.

### BACKGROUND OF THE INVENTION

The present invention relates to a soldering nozzle, and a method for the production thereof and a method for the selective soldering of an assembly.

A soldering fixture for selective soldering, having a solder bath for holding molten solder, at least one soldering nozzle, a solder pump for delivering solder from the solder bath through the soldering nozzle and a movement device for moving the soldering nozzle relative to an assembly to be soldered is known from DE 43 14 241 C2 or DE 10 2012 111 946 A1 or WO 2014/086954 A1, for example. An assembly (printed circuit board) is here conveyed into a soldering region, and the individual soldering points are sequentially soldered to one another by relative traversing movements of assembly and soldering nozzle.

A further selective soldering fixture emerges from DE 10 2007 002 777 A1, in which an assembly is deposited on a hood, and the hood is then together with the assembly lowered across an arrangement of a plurality of different nozzles. This involves a parallel soldering of a plurality—usually all—soldering points of the assembly. For differentiation, this procedure is described by the suppliers as “lift-dip soldering” or “multi-nozzle soldering”.

In the past few years selective soldering by means of a miniature wave has gained increasing currency. In this process the assembly to be soldered is moved above a small soldering nozzle by means of a positioning device and a work carrier or by means of direct board handling after wetting with flux and pre-heating, positioned accurately in the XY direction and lowered onto the nozzle for soldering. In direct board handling the assembly to be soldered lies directly on the conveying device. Following a soldering program, each point to be soldered is approached and soldered. Further details can for example be found in the article “Wellenlöten” (Wave Soldering), in particular in the section “Variationen” (Variations), subsection “Selektivlöten” (Selective Soldering) on the internet page http://de.wikipedia.org/wiki/Wellenlöten#Selektivlöten.

Wettable soldering nozzles for selective soldering have been produced as turned parts up to now. A first conventional example from the production of the applicant is a soldering nozzle 200 (FIGS. 2A-2D). This conventional soldering nozzle 200 has—consecutively—a cylindrical section 201 of a length L201 and an outer diameter (cylinder diameter) D201, a first conical section 202 of a length L202, a second conical section 203 of a length L203 and an outer diameter D203 at the transition to the first conical section 202 and a shoulder 204 of a length L204 and an outer diameter D204 at the end face. The second conical section 203 has a greater cone angle than the first conical section 202. All sections merge into one another without any jump in diameter. In the end face of the cylindrical section 201, a first bore 207 of a bore diameter D207 is formed, and in the end face of the second conical section a second bore 208 of a bore diameter D208 is formed, wherein D208>D207. The second bore 208 has a length L208 before merging into the first bore 207 by way of its bore base angle A208. In the outer surface of the second conical section 203, two radially opposite, identical, sickle-shaped holding notches 205 are formed, which are used for handling in the installation and removal process and which have a notch radius 8205 and a radial distance X205 from the longitudinal axis of the soldering nozzle 200 and a vertical distance H205 from the lower end face. At the lower end in the region of the shoulder 204 and the second conical section 203, there is further milled on one side an axially parallel flattening 206, which is used for the non-rotatable orientation of the nozzle in the holder at directed solder discharge and which has a minimum axial distance S206 from the longitudinal axis of the soldering nozzle 200 and merges into the adjoining outer surfaces with a radius 8206. At the end face of the cylindrical section 201, a curvature 211 with a curvature radius 8211 is formed at the outer circumference. The conventional soldering nozzle 200 has approximately the following dimensions for example: L201=21 mm, L202=19 mm, L203=19 mm, L204=1 mm, L208=15 mm, D201=8 mm, D203=20 mm, D204=36 mm, D207=4 mm, D208=12.2 mm, R205=6 mm, R206=3 mm, R211=1 mm, X205=12.5 mm, X205=15 mm.

The soldering nozzle 200 thus tapers from a lower end towards an upper end. The lower end forms a base by way of which the soldering nozzle is mounted on a soldering fixture, and for this reason the lower end will hereinafter be described as base end. The upper end forms a soldering nozzle tip and will for this reason hereinafter be described as tip end.

A second conventional example from the production of the applicant is a slimmer design of a soldering nozzle 300, which is designed as a pure turned part and is simpler in structure and more convenient in production than the first example (FIGS. 3A-3D). This conventional soldering nozzle 300 has—consecutively—a cylindrical section 301 of a length L301 and an outer diameter (cylinder diameter) D301 and a conical section 302 of a length L302 and a cone angle A302 ending in a base surface 304 with an outer diameter D304. All sections merge into one another without any jump in diameter. In the end face of the cylindrical section 301, a first bore 307 of a bore diameter D307 is formed, and in the end face of the conical section 302 a second bore 308 of a bore diameter D308 is formed, wherein D308>D307. The second bore 308 has a length L308 before merging into the first bore 307 by way of its bore base angle A308. At the end face of the cylindrical section 301, a curvature 311 with a curvature radius R311 is formed. There are no holding notches and one-sided flattening in this example. The conventional soldering nozzle 300 has approximately the following dimensions for example: L301=26 mm, L302=24 mm, L308=14 mm, A302−32.52°, D301=6 mm, D304=20 mm, D307=4 mm, D308=10.1 mm, R311=0.7 mm.

The nozzles, which are made of structural steel, are tin-plated after turning to ensure that they can be wetted with solder. For transport the nozzles are then stored in oil (e.g. rapeseed oil) to avoid oxidation. This oil has to be removed before the soldering nozzles are installed.

The comparatively great complexity involved in manufacture makes large-scale production difficult at present. There are however attempts at equipping soldering stations with more soldering nozzles in order to be able to selectively solder several soldering point of an assembly simultaneously.

From the above mentioned WO 2014/086954 A1 the combination of several soldering nozzles in groups and their joint traversing is known. In this process one or more soldering nozzle assemblies can be combined in one or more XY movement units. This requires a comparatively great number of soldering nozzles.

A further problem of the soldering nozzles produced in the conventional way involves their wall thickness, which can change along the length of the soldering nozzle in an irregular and spasmodic manner owing to production conditions. This results in an irregular thermal capacity along the length of the nozzle, and the heat transfer across the solder is variable along the length. As a result there may even be a risk that the solder could partially solidify if a cold nozzle is placed in the solder bath.

From DE 10 2017 123 806 A1 a soldering nozzle assembly provided for a lift-dip tool emerges. Such lift-dip tools have a plurality of soldering nozzles arranged adjacent to one another. In these soldering nozzles no soldering wave is generated at the upper edge of the nozzle opening, but because of the surface tension the solder forms a standing curvature into which pins of an object to be soldered dip in the soldering process. Slightly below the upper edge, such soldering nozzles have an opening through which solder can emerge. As a result solder can be conveyed in the soldering nozzle in a circuit, so that it is ensured that the solder is held at the temperature required for soldering in the upper region of the soldering nozzle as well. The soldering nozzle described here has a conical section and can be produced by deep drawing. Such a soldering nozzle assembly is always produced for a specific assembly and can only be used for said assembly.

In selective soldering, however, entirely different assemblies can be soldered with one soldering device, wherein the soldering nozzle is individually moved with respect to the assembly in accordance with a predetermined program, in order to contact the individual soldering point in sequence with the solder wave and to wet them with solder.

From DE 10 2013 110 731 B1 a soldering nozzle device with several separating strips emerges. The soldering nozzle device can be made of structural steel and coated with gold, nickel-gold and/or tin in the region of the separating strips.

### SUMMARY OF THE INVENTION

The present invention is based on the problem of providing a soldering nozzle and a method for the production of a soldering nozzle for selective soldering, with which the disadvantages of prior art can be avoided or reduced. Sub-problems of the present invention in particular relate to the provision of a soldering nozzle and a method for the production of a soldering nozzle which facilitate a simple and cost-effective production. Further sub-problems of the present invention relate to the provision of a soldering nozzle and a method for the production of a soldering nozzle which facilitate a uniform heat transfer when being heated by the solder and when cooling. Further sub-problems of the present invention relate to the provision of a soldering nozzle and a method for the production of a soldering nozzle which facilitate a simpler handling and installation of the soldering nozzle in a soldering fixture. A further sub-problem relates to the provision of a soldering nozzle for selective soldering which has a long service life.

At least a part of the above problems is solved by the subject matters of the independent claims. Advantageous embodiments and further developments of the invention are specified in the respective dependent claims.

A fundamental idea of the invention entails the production of a soldering nozzle as a deep-drawn part.

A soldering nozzle as envisaged by the invention is preferably an oblong, in particular axisymmetric or substantially axisymmetric hollow body with two open end faces, which hollow body is designed to carry a molten solder from the base end to the tip end, wherein the base end is in particular designed for accommodation in the region of a solder bath of a soldering fixture. A tip end therefore has an outflow opening for molten solder and a base end has an inflow opening for molten solder. The soldering nozzle can taper from the base end towards the tip end. The outflow opening can be narrower than the inflow opening in particular.

Deep-drawing is a forming method in which a blank, which is a cut piece of sheet metal or an already pre-drawn hollow body, is pressed into a new shape by tension and pressure. In this process an edge of the blank is held by a blank holder and a free part of the blank is pushed through a female die by a male die. The holding force of the blank holder is chosen such that the drawn part can slide along while forming the new shape and the formation of creases on the drawn part is avoided.

According to a first aspect of the invention, a soldering nozzle designed as a deep-drawn part is proposed.

In deep-drawing the wall thickness is constant or substantially constant in a production-immanent manner. The soldering nozzle therefore has a consistent thermal capacity along its entire length. The wall thickness is comparatively thin and therefore has a comparatively low thermal capacity. The installed soldering nozzle can therefore be heated through quickly, and the risk of the solder solidifying if a cold nozzle is deployed is reduced considerably.

The surface quality of deep-drawn parts is already very good when they fall out of the tool. In the deep-drawing process a very smooth surface, the so-called “drawing skin”, is produced. This does not have any score marks such as are unavoidable in turned parts, for example. This being so, mechanical finishing steps for smoothing the surface can be omitted. In a soldering nozzle this has the added advantage that the deposition of impurities, flux residues or oxides can be reduced.

Owing to the smooth surface of the deep-drawn part a very constant solder surface is obtained with the soldering nozzle according to the invention for selective soldering. With this soldering wave soldering points can be contacted and soldered very reliably and precisely.

The special surface quality improves resistance against the solder as well, i.e. the nozzle lasts longer before being attacked by the solder and worn. Soldering nozzles as a rule reach the end of their service life if they can no longer be wetted by soldering tin even if flux is added (e.g. because of impurities which cannot be removed or because of pitting). Experiments have shown that the service life of the deep-drawn soldering nozzles is considerably longer than that of conventional soldering nozzles.

Compared to machining processes, deep-drawing is simpler and involves lower production costs. The drawn nozzle also requires less material.

For a further improvement of the durability of the nozzle, it can be provided that it is provided with a finishing layer, which may for example be a layer of Ni (nickel) and/or a layer of Au (gold). The nickel layer can have a thickness of approximately 3-5 μm for example. In operation is has the advantage that it protects the steel against the solder and is to that effect a working layer having a permanent function in use. For a reliable function it is advantageous if the thickness of the nickel layer is at least approximately 1 μm. The nickel layer may be thicker, however, a sensible upper limit being approximately 20 μm. The gold layer can have a thickness of 0.2 μm for example. It provides an effective protection against oxidation in transport and storage. As a result the handling of oil and the cleaning of the nozzle before its placement can become expendable as well. In addition the gold layer is valuable in the initial wetting of the soldering nozzle since gold always wets. In operation the gold layer is lost, which corresponds to design, however, because once the soldering nozzle is tin-plated, a wetting aid is no longer required. To that effect it is therefore a lost layer, which is lost over time in use without restricting the function of the soldering nozzle. For a reliable function it is advantageous if the thickness of the gold layer is at least 0.1 μm. The gold layer may be thicker, however, a sensible upper limit being approximately 5 μm.

The finishing layer has the result that the good surface quality of the deep-drawn soldering nozzle is maintained for a long time. Trials have shown that in a conventional soldering nozzle for selective soldering, which has a turned surface, a finishing layer extends the service life of the soldering nozzle by approximately 20-30%. After this the surface is impaired in such a way that the solder no longer wets the surface evenly and the soldering wave is no longer stable. Such a soldering nozzle can then no longer be used. The trials show that in deep-drawn soldering nozzles with an outer surface provided with a finishing layer, service life becomes twice to three times as long. In this it has to be taken into account that the service life of the deep-drawn soldering nozzle is actually longer than that of a conventional soldering nozzle for selective soldering, in which the surface is produced by turning.

The combination of the deep-drawn surface—the drawing skin—and the finishing layer results in a surprisingly long service life or period of use for the soldering nozzle for selective soldering, because the soldering wave produced therewith is stable for a significantly longer period.

The contour of the soldering nozzle can be adapted to the deep-drawing method in a particularly advantageous way.

The soldering nozzle can have a first section of an approximately hollow-cylindrical shape of a first diameter, a second section of linearly increasing diameter adjoining the first section and a third section of an approximately hollow-cylindrical shape of a second diameter adjoining the second section, wherein the first section has at its end face a tip end with an outflow opening for molten solder and wherein the third section has at its end face a base end with an inflow opening for molten solder. In this way the desired structure of a comparatively wide solder reservoir region and a comparatively narrow solder exit region, which also facilitates a higher flow rate, is implemented. The contour is matched to the deep-drawing method.

The first section can have a curvature at the outer circumference at the tip end. The curvature facilitates the laminar flow-off of unused solder at the outer wall of the soldering nozzle back into the solder bath. The curvature can be a remnant from the deep-drawing process.

The third section can have a brim in the form of a disc-shaped cross-sectional widening at the base end. The brim may form a level standing surface which can be held by a holding device of a soldering fixture in a particularly simple way. Since said brim corresponds to a region in which the blank is gripped by the deep-drawing tool, this form is matched to the deep-drawing method in a particularly advantageous way as well. The brim preferably merges with a curvature into the cylindrical part of the third section. This makes the deep-drawing easier and facilitates a laminar solder feed.

The soldering nozzle can be produced from steel. A steel having magnetic properties is used to advantage. As a result a commonly available holding device can be used. With the brim described above in particular, a comparatively large magnetic holding surface can be obtained at a low mass. The steel 1.0330DC01 according to DIN EN 10130 (“DC01” in short) can be used for example. This has been found to be particularly suitable for parts that can be wetted by solder.

The soldering nozzle is tubular in design and has no further opening between a lower solder entry opening and an upper solder exit opening, so that a continuous flow through the soldering nozzle is ensured and a uniform soldering wave can be generated.

According to a further aspect of the invention, a method for the production of a soldering nozzle for selectively soldering assemblies by means of molten solder supplied through a soldering nozzle from a solder bath is proposed, the method comprising the following steps:
the provision of a blank;
the drawing of the blank through at least one female die to produce an oblong shape of locally annular or substantially annular cross-section, with a first end corresponding to an action point of the male die and a second end corresponding to an introduction cross-section of the male die, the cross-section preferably increasing from the first end towards the second end; and
the formation of an opening at the tip end.

The blank can be provided in the form of a circular blank. The provision of the blank may also comprise stamping from a strip or sheet metal. The blank may consist of steel such as “DC01” or another, in particular magnetic, type. The steel may also be a type wettable by solder. This is not compulsory, however, because wettability is obtained by chemical or galvanic pretinning or by way of the nickel/gold layer. The blank can have a thickness of at least 0.5 mm, preferably at least 1 mm and in particular at least 1.5 mm and/or of no more than 3 mm, preferably no more than 2.25 mm and in particular no more than 1.5 mm. A thickness of the blank approximately corresponds to a wall thickness of the soldering nozzle.

The opening at the tip end can be formed by stamping or drilling or by removing a part of the tip end, for example by cutting, milling, shearing away or the like.

The method can comprise the formation of a brim in the form of an approximately disc-shaped widening at the base end. The brim can be an edge of the blank which remains between the female die and the blank holder after drawing. The formation can also comprise a stamping or cutting or edging of the brim to shape or to measure following the drawing process.

A multi-stage deep-drawing tool can be used in the method. In a multi-stage tool the tool can be adapted from one stroke to the next, e.g. by using different male dies. This comparatively cost-effective procedure can in particular be advantageous for the production of prototypes and small quantities. The following sections can for example be provided in the sequence:
the stamping of a round blank from a strip
the repeated deep-drawing of the nozzle tip with increasing diameters
the punching of the solder exit hole
calibration

A progressive compound tool can be used in the method. In the case of a progressive compound tool the workpiece is typically conveyed from station to station, with individual steps with their own male/female dies being provided for in each case. In this way a high degree of automation can be achieved.

The method can comprise a coating with a finishing layer. The coating can comprise nickel and/or gold plating. The nickel plating can be applied before the gold plating. Concrete nickel or gold plating procedures are known to those skilled in the art and are selected in accordance with requirement and suitability. The nickel plating can be applied galvanically or chemically in particular. The gold plating can be applied galvanically or chemically or by vapour deposition (PVD, CVD) in particular. The nickel plating can be applied up to a coat thickness of approximately 3-5 μm. The gold plating can be applied up to a coat thickness of approximately 0.2 μm in particular. Depending on the method, it may be advantageous to apply an additional starting layer before the nickel layer. The starting layer can be a so called flash copper, for example.

A further aspect of the following invention relates to a method for the selective soldering of assemblies, wherein molten solder is fed through the soldering nozzle from a solder bath. This method is characterised in that a soldering nozzle made from a deep-drawn part is used.

As explained above, this creates a very stable soldering wave, in particular a mini-wave, over a long period of time, which runs along the outer surface of the soldering nozzle. The smooth drawing skin of the soldering nozzle makes the soldering wave very stable and the surface of the soldering wave very constant. This results in a significant quality improvement in selective soldering and furthermore in cost savings, because such a soldering nozzle can be used much longer for selective soldering than conventional soldering nozzles.

The soldering nozzle used in this process can be developed further as described above. It can in particular be provided with a finishing layer.

As explained at the beginning with reference to prior art, a miniature wave is generated by means of the soldering nozzle in selective soldering. Corresponding methods and devices are disclosed in DE 43 14 241 C2 or DE 10 2012 111 946 A1, to the contents of which reference is made.

In general, according to still another aspect, the invention features a soldering method comprising providing a blank, drawing of the blank through at least one female die by means of at least one male die to produce an oblong shape of locally annular or substantially annular cross-section, with a first end corresponding to an action point of the male die and a second end corresponding to an introduction cross-section of the male die, the cross-section increasing from the first end towards the second end, forming an opening at the tip end, and selectively soldering assemblies with molten solder by supplying the molten solder from a solder bath through the opening to the assemblies.

The above and other features of the invention including various novel details of construction and combinations of parts, and other advantages, will now be more particularly described with reference to the accompanying drawings and pointed out in the claims. It will be understood that the particular method and device embodying the invention are shown by way of illustration and not as a limitation of the invention. The principles and features of this invention may be employed in various and numerous embodiments without departing from the scope of the invention.

### BRIEF DESCRIPTION OF THE DRAWINGS

In the accompanying drawings, reference characters refer to the same parts throughout the different views. The drawings are not necessarily to scale; emphasis has instead been placed upon illustrating the principles of the invention. Of the drawings:

FIG. 1 is a diagrammatic representation of a soldering nozzle according to an embodiment of the present invention in longitudinal section;

FIGS. 2A to 2D are diagrammatic representations of a conventional soldering nozzle in a perspective full view, a view from below, a side view and a longitudinal section along a line D-D in FIG. 2C;

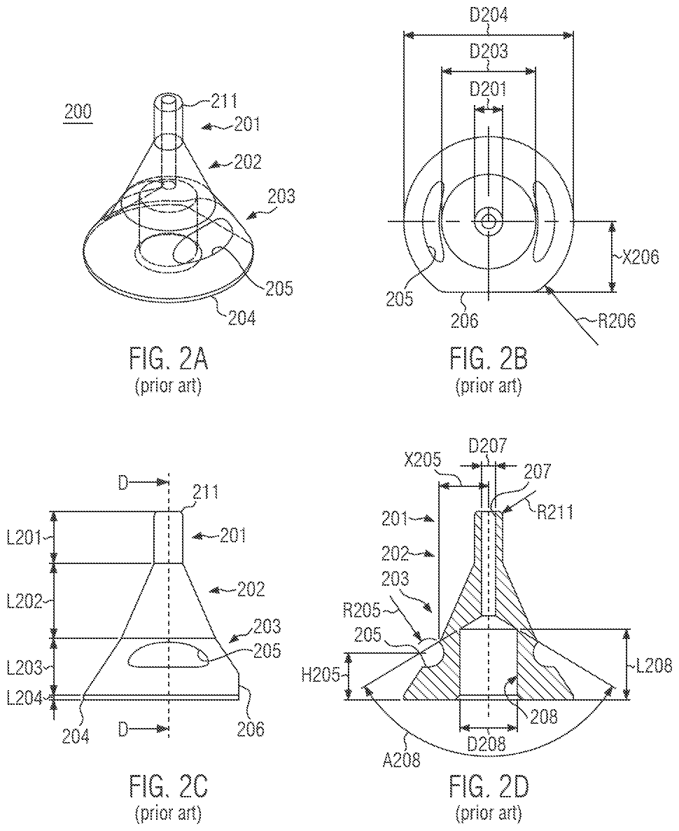

FIGS. 3A to 3D are diagrammatic representations of another conventional soldering nozzle in a perspective full view, a view from below, a side view and a longitudinal section along a line D-D in FIG. 3C; and

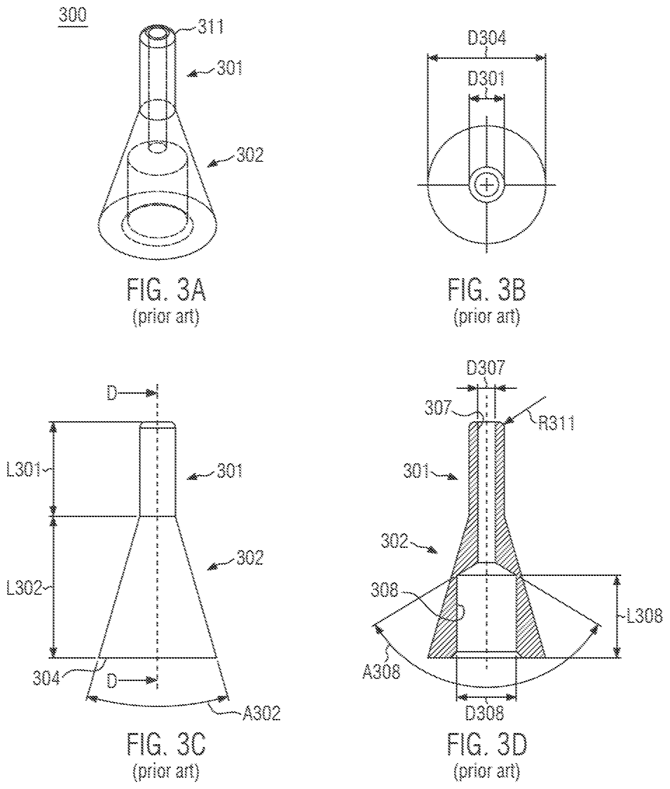

FIGS. 4A to 4F are diagrammatic representations of procedural steps of a method for the production of the soldering nozzle from FIG. 1 according to an embodiment of the invention.

### DETAILED DESCRIPTION OF THE PREFERRED EMBODIMENTS

The invention now will be described more fully hereinafter with reference to the accompanying drawings, in which illustrative embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

As used herein, the term “and/or” includes any and all combinations of one or more of the associated listed items. Further, the singular forms and the articles “a”, “an” and “the” are intended to include the plural forms as well, unless expressly stated otherwise. It will be further understood that the terms: includes, comprises, including and/or comprising, when used in this specification, specify the presence of stated features, integers, steps, operations, elements, and/or components, but do not preclude the presence or addition of one or more other features, integers, steps, operations, elements, components, and/or groups thereof. Further, it will be understood that when an element, including component or subsystem, is referred to and/or shown as being connected or coupled to another element, it can be directly connected or coupled to the other element or intervening elements may be present.

It will be understood that although terms such as “first” and “second” are used herein to describe various elements, these elements should not be limited by these terms. These terms are only used to distinguish one element from another element. Thus, an element discussed below could be termed a second element, and similarly, a second element may be termed a first element without departing from the teachings of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

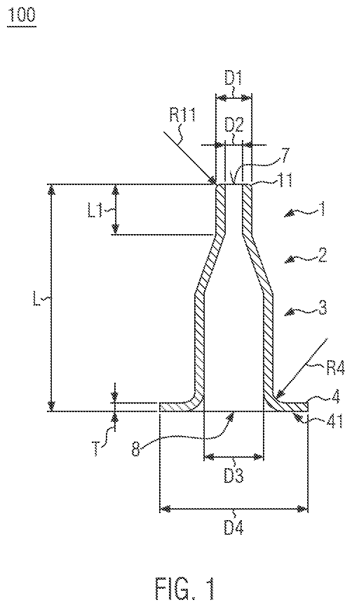

The soldering nozzle 100 is designed as a deep-drawn part. The soldering nozzle 100 is an oblong, axisymmetric hollow body with two open end faces, a tip end 7 and a base end 8 and a substantially constant wall thickness T (FIG. 1). The soldering nozzle is designed to carry molten solder from the base end to the tip end, the base end being in particular designed for accommodation in the region of a solder bath of a soldering fixture (not shown in detail). The tip end 7 thus has an outflow opening for molten solder and the base end 8 has an inflow opening for molten solder. The soldering nozzle 100 tapers from the base end 8 towards the tip end 7. The outflow opening may in particular be narrower than the inflow opening. The soldering nozzle is thus in particular designed for use in a soldering fixture for the selective soldering of assemblies.

The soldering nozzle 100 can be produced from steel. The steel type used can be selected with regard to a good wettability for solder. The selected steel type can be magnetic, which offers advantages in handling and installation, since the soldering nozzle 100 can then be handled and held using magnetic devices. The steel 1.0330DC01 according to DIN EN 10130 (“DC01” in short) can be used for example. This has been found to be particularly suitable for parts that can be wetted by solder and is magnetic as well.

The surface quality of deep-drawn parts is typically very good and in particular smooth, which facilitates their use as flow passages for solder and can extend their service life considerably. The soldering nozzle 100 can in addition be provided with a finishing layer such as an Ni—Au alloy for example or a two-layer coating of Ni (nickel) on the one hand and Au (gold) on the other hand, so that the soldering nozzle is protected against the solder by the nickel component on the one hand and its wettability is improved by the gold component on the other hand and it can be stored without any problems.

The soldering nozzle 100 can have a first section 1 of an approximately hollow-cylindrical shape of an outer diameter D1 and an inner diameter D2, a second section 2 of linearly increasing diameter adjoining the first section 1 and a third section 3 of an approximately hollow-cylindrical shape of an inner diameter D3 adjoining the second section 2. The first section 1 can have the tip end 7. The third section 3 can have the base end 8. The third section 3 with the comparatively wide cross-section can serve as a solder reservoir region, and the first section 1 with the comparatively narrow cross-section can serve as a solder exit region facilitating a higher flow rate as well. The contour of the soldering nozzle 100 is on the whole adapted to the deep-drawing method.

The first section 1 can have a curvature 11 at the tip end 7 at its outer circumference. The curvature 11 facilitates the laminar flow-off of unused solder at the outer wall of the soldering nozzle 100 back into the solder bath. The curvature 11 can be a remnant from the deep-drawing process, as will be described in greater detail at a later point. The curvature 11 can be produced mechanically or reworked.

The third section 3 can have a brim 4 in the form of a disc-shaped cross-sectional widening at the base end 8. The brim 4 may form a level standing surface 41 which can be held by a holding device of a soldering fixture in a particularly simple way. The standing surface 41 can for example offer a large magnetic surface to a magnetic holding device in a soldering fixture and thus be held in a particularly stable position. The brim 4 also corresponds to a region in which the blank is still gripped by the blank holder of the deep-drawing tool at the end of the deep-drawing process and is therefore adapted to the deep-drawing method in a particularly advantageous way. The brim 4 can merge into the cylindrical part of the third section 3 with a curvature 41. This makes deep-drawing easier and facilitates a laminar inflow of the solder.

The dimensions of the soldering nozzle 100 can be adapted to the respective application. In a typical embodiment an overall length of the soldering nozzle 100 may be approximately 40 mm, a wall thickness T of the soldering nozzle 100 approximately 1.5 mm, an inner diameter D2 of the first section 1 at the tip end 7 (the outflow opening) approximately 4 mm (the outer diameter D1 thus being approximately 7 mm), the length of the first section 1 approximately 10 mm, an inner diameter D3 of the third section 3 at the base end 8 before the transition to the brim 4 approximately 10 mm, an outer diameter D4 at the outer circumference of the brim 4 approximately 25 mm and a curvature radius R4 at the transition from the cylindrical part of the third section 3 to the brim 4 approximately 2 mm. A curvature radius R4 may correspond to the wall thickness T and be approximately 1.5 mm in this embodiment. The optional finishing layer (not shown in the drawing) can have a first layer of approximately 3-5 μm nickel and a second layer of approximately 0.2 μm gold.

The inner diameter D3 of the third section 3 and the outer diameter D4 of the brim 4 can be adapted to an existing holding or reception fixture. For such an application these values can therefore be predetermined. The diameters D1, D2 of the first section 1 are more variable, however, although subjected to an upper limit by the inner diameter D3 of the third section 3, because it is impossible to produce a deep-drawn part which has a greater diameter towards the top than at the bottom in the region of the brim 4. If the soldering nozzle 100 requires a greater diameter at the first section 1, the inner diameter D3 at the section 2 has to be increased as well (e.g. to 20 mm), and a suitable holding fixture has to be provided at the soldering fixture.

A staggered system with nozzle holders for bottom diameters D3 in a predetermined stacking arrangement can be advantageous as well. This means that soldering nozzles 100 with a top diameter D2 of maximally a first stacking stage have the bottom diameter D3 of said stacking stage (e.g. 10 mm) and are pushed onto nozzle holders for said diameter, soldering nozzles 100 with a top diameter D2 above the first stacking stage and of maximally a second stacking stage have the bottom diameter D3 of the second stacking stage (e.g. 20 mm) and are pushed onto nozzle holders for said diameter, and so on.

In principle the bottom diameter D3 is greater than the top diameter D1 at the tip. The bottom diameter D3 can be adapted to a greater top diameter D1, i.e. for all nozzle geometries of a production series the bottom diameter D3 can correspond to the bottom diameter D3 designed for the maximum top diameter D1. This offers a greater variability in terms of the top diameter D1. The bottom diameter D3 can also be adapted to a large nozzle holder at a soldering machine. In such a case adapters can be provided which facilitate installation into smaller nozzle holders as well. This also facilitates the production of larger quantities of soldering nozzles of a standard size which can be used for different nozzle holders or machines.

The soldering nozzle 100 is designed for the selective soldering of assemblies by a molten solder supplied from a solder bath by the soldering nozzle.

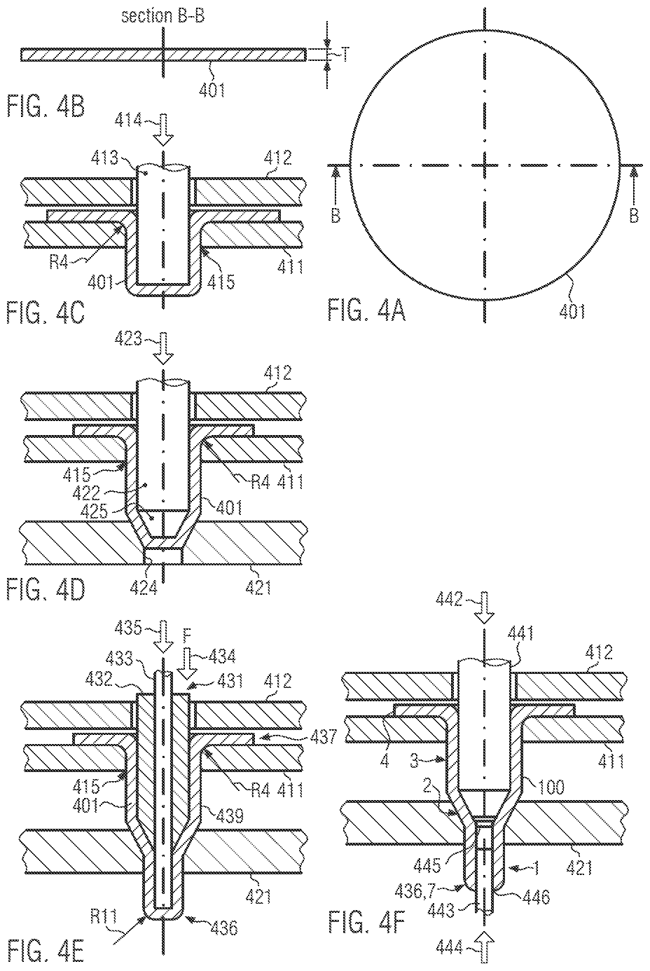

A method for the production of the soldering nozzle 100 can essentially comprise the following steps:
the provision of a blank 401 (FIGS. 4A, 4B);
the drawing of the blank 401 through at least one female die 411, 412 to produce an oblong shape 439 of locally annular or substantially annular cross-section, with a first end 436 corresponding to an action point of the male die 413, 422, 431 and a second end 437 corresponding to an introduction cross-section of the male die 413, 422, 431, the cross-section preferably increasing from the first end 436 towards the second end 437 (FIGS. 4C-4R); and
the formation of an opening 436 at the first end 436, which corresponds to the tip end 7 of the finished soldering nozzle 100.

The blank 401 can be provided in the form of a circular blank (FIG. 4A). The blank 401 can for example be produced by stamping from a strip or sheet metal and can have a thickness corresponding to a wall thickness T of the soldering nozzle 100 (FIG. 4B). In the present embodiment the wall thickness T can be 1.5 mm. Depending on the application, the wall thickness T can be more then 1.5 mm, for example approximately 2.25 mm or 3 mm, or less, for example approximately 1 mm or 0.5 mm. The blank 401 can be made of steel such as “DC01” or another, in particular magnetic, type. In some cases it can be advantageous if the steel has the property of wettability by solder, in particular of the soldering nozzle 100 is not coated with a wetting agent.

The blank 401 can be placed on a first female die 411 with a hole 415, so that the center of the blank 401 coincides with the axis of the hole 415, and pressed against the first female die 411 by a blank holder 412 (FIG. 4C). The hole 415 has a diameter which corresponds to the outer diameter of the eventual third section 3 of the soldering nozzle 100 (cf. FIG. 1). The hole 415 further has a curvature at its top circumference, the radius of which corresponds to the eventual rim radius R4 of the soldering nozzle 100 (cf. FIG. 1). A first male die 413 with an outer diameter corresponding to the inner diameter D3 of the eventual third section 3 of the soldering nozzle 100 approaches the hole 415 coaxial with its center in a feed direction 414 and draws the blank 401 to a length corresponding to a length of the eventual third section 3 of the soldering nozzle 100. To complete this procedural step, the first male die 413 pulls out in the opposite direction.

Following this, the first female die 411 can be placed with the blank 401 above a second female die 421 with an opening 424, so that an axis of the hole 415 coincides with that of the opening 424 (FIG. 4D). The opening 424 of the second female die 421 has a contour corresponding to an outer contour of the eventual second section 2 and an adjoining transition region in the eventual section 1 (cf. FIG. 1). A second male die 422 with an outer diameter corresponding to the inner diameter D3 of the eventual third section 3 of the soldering nozzle 100 and with a conical end with an outer contour corresponding to the inner contour of the eventual second section 2 of the soldering nozzle 100 then approaches in a feed direction 423 coaxial with a center of the hole 415 and the opening 525 and draws the blank 401 to a length and a contour corresponding to the length and contour of the eventual second section 2 of the soldering nozzle 100. To complete this procedural step, the second male die 422 pulls out in the opposite direction.

Following this, a third male die 431 can be inserted into the already formed cavity of the blank 401 up to the stop while maintaining (or changing as suitable) the positions of the blank 401, the first female die 411 and the second female die 421 (FIG. 4E). The third male die 431 is multi-part, with an outer die 432 and an inner die 433 axially movable in an axial bore of the outer die 432. The outer die 432 has an outer contour corresponding to the inner contour of the eventual third part 3 and the eventual second part 2 of the soldering nozzle 100 (cf. FIG. 1). The axial bore of the outer die 432 has a bore diameter corresponding to the inner diameter D2 of the eventual first section 1 of the soldering nozzle 100, as does an outer diameter of the inner die 433. The outer die is then pressed against the blank 401 in a holding direction 434 with a force F which is chosen such that the outer die 432 acts as an auxiliary blank holder against the second female die 421 when the inner die 433, guided by the axial bore of the outer die 432, approaches in a feed direction 435 and draws the blank 401 through the second female die 421 to a length and contour corresponding to a length and contour of the eventual first section 1 of the soldering nozzle 100. To conclude this procedural step, the inner die 433 reverses in the opposite direction and moves completely out of the blank 401 together with the outer die 432. It should be noted that the curvature radius R11 of the finished soldering nozzle 100 can already be formed at the first end 436 at the end of this procedural step by drawing to final length.

Following this, a fourth male die 441 can be inserted into the already formed cavity of the blank 401 up to the stop while maintaining (or changing as suitable) the positions of the blank 401, the first female die 411 and the second female die 421 (FIG. 4F). The fourth male die 441 corresponds to the second male die 422 in its shape while having a shorter conical end. The fourth male die 441 is then pressed against the blank 401 in a holding direction 422 in order to fix it relative to the second female die 421. A stamping mandrel 443 with an outer diameter corresponding to the inner diameter of the first section 1 of the soldering nozzle 100 then approaches from the outside in a feed direction 444 coaxial with the axial direction of the fourth male die 441 against the holding direction 442 thereof, in order to form an opening 446 in the first end 436 of the blank, which end now corresponds to a tip end 7 of the soldering nozzle 100. A stamping residue 445 is pushed through the first section 1 into a cavity of the second section 2, where it remains loosely and can fall out of the of the drawing tool when the soldering nozzle 100 is removed from the drawing tool. To conclude this procedural step, the stamping mandrel 443 and the fourth male die 441 reverse in the opposite direction and move out of the now finish-drawn soldering nozzle 100.

The soldering nozzle 100 is now removed from the tool and can be turned upside down to remove the stamping residue 445.

The opening 446 can optionally be reworked in terms of its shape, dimensions and/or surface quality.

The edge of the blank 401, which remains in the drawing process between the first female die 411 and the blank holder 412 and now forms the brim 4 of the soldering nozzle 100, can optionally be reworked to shape (calibrated).

After its removal the soldering nozzle 100 can in addition to be nickel- and/or gold-plated to form the finishing layer described above. Those skilled in the art are familiar with many variants of these procedural steps, which therefore do not have to be described here. The action time of the respective baths will be dimensioned by those skilled in the art in such a way that the desired coating thickness is obtained.

The method described above can be modified depending on the shape of the soldering nozzle 100 and in procedural respect.

The strokes of the male dies 413, 423 and 431 can be limited by depth stops, for example. Such depth stops can be provided at the die lining or as a seating surface for the drawn end of the blank 401.

The female dies may also be designed such that the blank is supported and guided from the outside during the entire drawing process.

When stamping out the opening 446 (FIG. 4F), the first section 1 can be enclosed by an annular sleeve (not shown) to avoid bulging or bending out of shape.

Multiple variations and supplements are conceivable for stamping out the opening 446 (FIG. 4F). Instead of the fourth male die 411, the second male die 422 or the third male die 431 can be used as an alternative, for example, if the stamping residue 455 is pushed still further into the cavity of the second section 2 with the aid of the stamping mandrel 443 after removing the second male die 422 or the third male die 431. If the third male die 431 is used for stamping out the opening 446 (FIG. 4F), the stamping residue 455 can also be pushed out with the aid of the inner die 433 or pushed into the axial bore of the outer die 432 with the aid of the stamping mandrel 443 after removing the stamping mandrel 443, or it can be removed from the soldering nozzle 100 together with the third male die 431 and then pushed out with the aid of the inner die 433. In a further variation the third male die 431 can be used in place of the stamping mandrel 443, which acts from the outside, to stamp out the opening 446 from the inside. For this purpose the inner die 433 can be designed as a stamping mandrel, or the inner die 433 can be replaced by a separate stamping mandrel after the blank 401 has been drawn to final length, and the opening 446 can be stamped out in an outward direction. In this process it would be advantageous to place a third female die (not shown) having a hole with a hole diameter corresponding to the outer diameter of the stamping mandrel below the first end 436 of the blank 401 (FIG. 4E).

Apart from the above, further methods for forming the opening 446 are conceivable as well, such as drilling or the removal of a part of the first end, perhaps by cutting, milling, shearing off or the like. When removing a part of the first end 446, the curvature radius R11 (cf. FIG. 1) would then have to be formed afterwards.

It should be noted that, as a result of the continuous drawing of the blank, an edge of the blank finally remains between the female die 411 and the blank holder 412; this edge then forms the brim 4 of the soldering nozzle 100 in the form of an approximately disc-shaped widening. If required, the brim 4 can optionally be machined to shape or dimension (calibrated) by stamping or cutting or edging.

Apart from this, the method illustrated and described here is only an example for carrying out the claimed method, its application being in no sense limited to the individual steps and measured described here. Depending on the shape of the soldering nozzle 100, it is conceivable to use only a single male die for drawing the blank 401 to shape and length in a single drawing step. Even the soldering nozzle 100 described here, with its specific shape, could if necessary be produced using a single male die reproducing the inner contour of the soldering nozzle 100. It is possibly advantageous to draw initially the first section 1, then the second section 2 and then the third section 3 with the brim 4, using several female dies consecutively. A plurality of male and female dies can be used in a plurality of individual steps in order to draw the soldering nozzle in sections to the various diameters.

In some variations the sequence of the drawing steps can be reversed, i.e. it is possible to form the tip with the narrowest diameter first and then widen the diameter of the adjoining sections progressively. In such variations the male die with the largest diameter can therefore be used last.

A multi-stage deep-drawing tool or a progressive compound tool can be used in the method. Such tools can work in linear or rotational sequence.

The fundamental ideal of the method is obviously based on the deep-drawing of the soldering nozzle. The procedural steps and tool forms described above are purely exemplary. The soldering nozzle according to the invention is described and illustrated purely by way of example. Details can be varied in a suitable way as required by those skilled in the art. The invention is in particular defined by the appended claims only and is not restricted by embodiment details described above. Individually described or illustrated features can be added or omitted individually or in combination with further described or illustrated features or subject matters thereof or another embodiment in order to form independent subject matters of the invention.

### LIST OF REFERENCE NUMBERS

100 Soldering nozzle
1 First section
2 Second section
3 Third section
4 Brim
7 Tip end
8 Base end
11 Curvature
41 Standing surface
D1 Outer diameter 1st section
D2 Inner diameter 1st section
D3 Inner diameter 3rd section
D4 Outer diameter brim
L Nozzle length
L1 Length of first section
R4 Brim radius
R11 Curvature radius
T Wall thickness
200 Soldering nozzle (prior art)
201 Cylindrical section
202 First conical section
203 Second conical section
204 Shoulder
205 Holding notch
206 Flattening
207 First bore
208 Second bore
211 Curvature
A208 Bore base angle
D201 Cylinder diameter
D204 Base diameter
D207 First bore diameter
D208 Second bore diameter
L201 Length of cylindrical section
L202 Length of 1st conical section
L203 Length of 2nd conical section
L208 Bore length
R201 Curvature radius
R205 Notch radius
X206 Axial distance of flattening
300 Soldering nozzle (prior art)
301 Cylindrical section
302 Conical section
304 Base surface
307 First bore
308 Second bore
311 Curvature
A302 Cone angle
A308 Bore base angle
D301 Cylinder diameter
D304 Base diameter
D307 First bore diameter
D308 Second bore diameter
L301 Length of cylindrical section
L302 Length of conical section
L308 Bore length
R301 Curvature radius
401 Blank
411 First female die
412 Blank holder
413 First male die
414 Feed direction
415 Hole
421 Second female die
422 Second male die
423 Feed direction
424 Opening
425 End
431 Third male die
432 Outer die
433 Inner die
434 Holding direction
435 Feed direction
436 First end
437 Second end
439 Oblong shape
441 Fourth male die
442 Holding direction
443 Stamping mandrel
444 Feed direction
445 Stamping residue
446 Opening

While this invention has been particularly shown and described with references to preferred embodiments thereof, it will be understood by those skilled in the art that various changes in form and details may be made therein without departing from the scope of the invention encompassed by the appended claims.

What is claimed is:

1. A soldering nozzle for selectively soldering assemblies with molten solder supplied through the soldering nozzle from a solder bath, wherein the soldering nozzle is designed as a deep-drawn part.

2. The soldering nozzle according to claim 1, wherein the soldering nozzle is provided with a finishing layer comprising a layer of Ni (nickel) and/or a layer of Au (gold), the nickel layer being a working layer, the gold layer being a lost layer.

3. The soldering nozzle according to claim 1, wherein the contour of the soldering nozzle (100) is adapted to the deep-drawing method.

4. The soldering nozzle according to claim 1, wherein the soldering nozzle has a first section of an approximately hollow-cylindrical shape of a first diameter, a second section of linearly increasing diameter adjoining the first section and a third section of an approximately hollow-cylindrical shape of a second diameter adjoining the second section, wherein the first section has at its end face a tip end with an outflow opening for molten solder and wherein the third section has at its end face a base end with an inflow opening for molten solder.

5. The soldering nozzle according to claim 4, wherein the first section has a curvature at the outer circumference at the tip end.

6. The soldering nozzle according to claim 4, wherein the third section has a brim in the form of a disc-shaped cross-sectional widening at the base end, wherein the brim forms a level standing surface, wherein the brim merges with a curvature into the cylindrical part of the third section.

7. The soldering nozzle according to claim 1, wherein the soldering nozzle is produced from steel preferably having magnetic properties, the steel type used being 1.0330DC01 according to DIN EN 10130.

8. A method for the production of a soldering nozzle for selectively soldering assemblies with molten solder supplied through a soldering nozzle from a solder bath, the method comprising:
the provision of a blank;
the drawing of the blank through at least one female die by means of at least one male die to produce an oblong shape of locally annular or substantially annular cross-section, with a first end corresponding to an action point of the male die and a second end corresponding to an introduction cross-section of the male die, the cross-section increasing from the first end towards the second end; and
the formation of an opening at the tip end.

9. The method according to claim 8, wherein the blank is provided in the form of a circular blank, by stamping from a strip or sheet metal.

10. The method according to claim 8, wherein the blank is produced from steel having magnetic properties, the steel type used being 1.0330DC01 according to DIN EN 10130.

11. The method according to claim 8, wherein the blank has a thickness of at least 0.5 mm, preferably at least 1 mm and in particular at least 1.5 mm and/or of no more than 3 mm, preferably no more than 2.25 mm and in particular no more than 1.5 mm, wherein a thickness of the blank approximately corresponds to a wall thickness of the soldering nozzle.

12. The method according to claim 8, wherein the opening at the first end is formed by stamping or drilling or by removing a part of the first end (436), for example by cutting, milling, shearing away or the like.

13. The method according to claim 8, wherein a brim in the form of a disc-shaped cross-sectional widening is formed at the second end, the brim being an edge of the blank which remains between the female die and the blank holder after drawing, the brim being machined to shape or measure by stamping or cutting or edging after drawing.

14. The method according to claim 8, wherein a multi-stage deep-drawing tool and/or a progressive compound tool is used.

15. The method according to claim 8, further comprising a coating with a finishing layer, the coating process comprising a nickel and/or gold plating, wherein the nickel plating precedes the gold plating, the nickel layer being designed as a working layer, the gold layer preferably being designed as a lost layer.

16. A method for the selective soldering of an assembly, wherein molten solder is fed to the assembly through a soldering nozzle from a solder bath, wherein the soldering nozzle formed from a deep-drawn process.

17. The method according to claim 16, wherein the soldering nozzle has a first section of an approximately hollow-cylindrical shape of a first diameter, a second section of linearly increasing diameter adjoining the first section and a third section of an approximately hollow-cylindrical shape of a second diameter adjoining the second section, wherein the first section has at its end face a tip end with an outflow opening for molten solder and wherein the third section has at its end face a base end with an inflow opening for molten solder.

18. A soldering method comprising:
providing a blank;
drawing of the blank through at least one female die by means of at least one male die to produce an oblong shape of locally annular or substantially annular cross-section, with a first end corresponding to an action point of the male die and a second end corresponding to an introduction cross-section of the male die, the cross-section increasing from the first end towards the second end; and
forming an opening at the tip end; and
selectively soldering assemblies with molten solder by supplying the molten solder from a solder bath through the opening to the assemblies.
